(19) United States
(12) Patent Application Publication
(10) Pub. No.: US 2026/0026304 A1
(43) Pub. Date: Jan. 22, 2026

(54) ELECTROSTATIC CHUCK WITH PROTECTIVE COATING

(71) Applicant: ENTEGRIS, INC., Billerica, MA (US)

(72) Inventors: Carlo Waldfried, Middleton, MA (US); Jianan Hou, Lexington, MA (US); Jakub Rybczynski, Arlington, MA (US)

(21) Appl. No.: 19/270,269

(22) Filed: Jul. 15, 2025

Related U.S. Application Data
(60) Provisional application No. 63/671,839, filed on Jul. 16, 2024.

(51) Int. Cl. H01L 21/683; C23C 16/458

(52) U.S. Cl. CPC H01L 21/6833; C23C 16/4581; C23C 16/4582

(57) ABSTRACT

Electrostatic chucks, as described herein, can include at least a first layer, a second layer including an organic material, an encapsulation coating, and a third layer. The second layer is located between the first and third layer such that at least a portion of the second layer is not covered. The encapsulation coating covers at least the portion of the second layer that is not covered. The encapsulation coating can be formed by atomic layer deposition or by chemical vapor deposition such that it encapsulates at least the uncovered portion of the second layer.

### CROSS-REFERENCE TO RELATED APPLICATION

This Application claims the benefit of and priority to U.S. Provisional Application No. 63/671,839, filed on Jul. 16, 2024 the entirety of which is incorporated herein by reference for all purposes.

### FIELD

This disclosure relates to electrostatic chucks with protective coatings and related methods.

### BACKGROUND

Electrostatic chucks are high voltage electrical devices useful in the semiconductor manufacturing processes. During use of the electrostatic chuck, the back side of a substrate, such as a semiconductor wafer, is held to the face of the electrostatic chuck by an electrostatic force such that the wafer contacts a dielectric layer of the electrostatic chuck. During use, the electrostatic chucks can be exposed to different types of environments including oxidizing environments.

### SUMMARY

Some embodiments relate to an electrostatic chuck. In some embodiments, the electrostatic chuck includes a first layer. In some embodiments, the electrostatic chuck includes a second layer including an organic material. In some embodiments, the electrostatic chuck includes an encapsulation coating. In some embodiments, the electrostatic chuck includes a third layer. In some embodiments, the second layer is located between the first layer and the third layer such that at least a portion of the second layer is not covered by the first layer and the third layer. In some embodiments, the encapsulation coating covers at least the portion of the second layer that is not covered by the first layer and the third layer.

Some embodiments relate to a device. In some embodiments, the device includes an electrostatic chuck. In some embodiments, the electrostatic chuck includes a first layer. In some embodiments, the electrostatic chuck includes a second layer comprising an organic material. In some embodiments, the electrostatic chuck includes a third layer. In some embodiments, the electrostatic chuck includes an encapsulation coating. In some embodiments, the second layer is located between the first layer and the third layer such that at least a portion of the second layer is not covered by the first layer and the third layer. In some embodiments, the encapsulation coating covers is a conformal firm covering at least the portion of the second layer that is not covered by the first layer and the third layer.

Some embodiments relate to a method. In some embodiments, the method includes obtaining an electrostatic chuck. In some embodiments, the method includes placing an electrostatic chuck in a chamber of a deposition tool. In some embodiments, the electrostatic chuck includes a first layer. In some embodiments, the electrostatic chuck includes a second layer including an organic material. In some embodiments, the electrostatic chuck includes a third layer. In some embodiments, the second layer is located between the first layer and the third layer such that at least a portion of the second layer is not covered by the first layer and the third layer. In some embodiments, the method includes forming a vapor deposition layer on at least the portion of the second layer that is not covered by the first layer and the third layer.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a sectional side view of a device, according to some embodiments.

FIG. 2 is a sectional side view of a device, according to some embodiments.

FIG. 3 is a sectional side view of a portion of the device in FIG. 2, according to some embodiments.

FIG. 4 is a sectional side view of a device, according to some embodiments.

FIG. 5 is a sectional side view of a device, according to some embodiments.

FIG. 6 is a sectional side view of a device, according to some embodiments.

FIG. 7 is a non-limiting example a graph illustrating changes in chemical compositions at a device, according to some embodiments.

FIG. 8 is a flowchart of a method of forming a vapor deposition layer on an electrostatic chuck, according to some embodiments.

### DETAILED DESCRIPTION

Various embodiments of the present disclosure relate to devices and apparatus for an electrostatic chuck. The electrostatic chuck can have a body constructed of one or more layers. A layer can include one or more components therein. In some embodiments, the electrostatic chuck includes at least one layer including, but not limited to, a dielectric layer, an electrode layer, a bonding layer, an adhesive layer, an electrode circuit layer, an insulator layer, a heater circuit layer, an electrical isolation layer, or any combination thereof. In some embodiments, the electrostatic chuck can include a plurality of layers. In some embodiments, the electrostatic chuck can include at least one component including, but not limited to, an electrode contact pin, a heater contact pin, an electrical conductor, a heating element, sensors, other components, or any combination thereof. In some embodiments, at least one layer of the electrostatic chuck can include an organic material therein such as, for example and without limitation, a polymeric material. In some embodiments, the at least one layer including the organic material can be a thermoplastic made of polymeric materials. The electrostatic chuck can include an encapsulation coating serving as a vapor deposition layer, as will be further described herein.

Polymeric materials can include, but are not limited to, at least one of acrylate polymers, polyolefins, polyamides, polyethers, polycarbonates, polysulfones, vinyl polymers, fluoropolymers, other types of polymers, or any combination thereof. In some embodiments, the polymeric materials can include, but are not limited to, at least one of fluorinated ethylene propylene (FEP), fluoropolymer, high-density polyethylene (HDPE), low-density polyethylene (LDPE), medium-density polyethylene (MDPE), perfluoroalkoxy alkane (PFA), polybutylene (PB), poly(butyl acrylate) (PBA), poly(ethyl acrylate) (PEA), polyacrylonitrile (PAN), polyaryletherketone (PAEK), polybutadiene, polybutylene adipate terephthalate (PBAT), polybutylene succinate (PBS), polybutylene terephthalate (PBT), polychlorotrifluoroethylene (PCTFE or PTFCE), polyetherimide, polyethylene (PE), polyether ether ketone (PEEK), polyetherketoneketone (PEKK), polyethylene naphthalate (PEN), polyethylene terephthalate (PET), polyglycolide (PGA), polyphenyl sulfone (PPSU), polymethylpentene (PMP), polypropylene (PP), nylon, polyoxetane (POX), polyoxymethylene (POM), polyphenyl ether (PPE), polypropylene glycol (PPG), polystyrene (PS), polytetrafluoroethylene (PTFE), polyvinyl chloride (PVC), polyvinyl fluoride (PVF), polyvinylcarbazole (PVK), polyvinylidene chloride (PVDC), polyvinylidene fluoride (PVDF), or any combination thereof. or any combination thereof

The electrostatic chuck can include a plurality of layers. At least one layer of the electrostatic chuck can include the organic material. The at least one layer including the organic material can be disposed in a respective layer of the electrostatic chuck so that at least a portion of the layer including the organic material is or, if not covered, would be exposed to the external environment. That is, the at least one layer including the organic material can be disposed adjacent another layer of the electrostatic chuck or can be disposed between two or more other layers of the electrostatic chuck so that at least a portion of a surface of the at least one layer including the organic material that is not being covered by another layer of the electrostatic chuck is exposed to the external environment. For example, the layer including the organic material can be an electrical isolation layer located adjacent a ceramic insulator layer and one or more sides of the layer including the organic material that are not covered by the ceramic insulator layer can be exposed to the external environment. In another example, the layer including the organic material can be a bonding layer located between a dielectric layer and an insulator layer and the at least one sidewall of the layer including the organic material can be exposed to the external environment. It will be appreciated that the at least one layer including the organic material can include one or more other functional components, without departing from the scope of this disclosure.

The electrostatic chucks can be used in different types of environments. Accordingly, the electrostatic chucks can be exposed to different environmental conditions. When the electrostatic chuck is used in or exposed to oxidizing atmospheres, such as, for example, ozone treatments or H₂ plasma exposures, the organic materials forming the at least one layer of the electrostatic chuck can degrade or otherwise be damaged, which may result in premature failure of the electrostatic chuck. Surfaces of the electrostatic chuck that are formed of or comprise organic materials may be located in areas of the electrostatic chuck that are difficult to access, such as structures having high aspect ratios. For example, the at least one layer including the organic material can be sandwiched between two other layers or components. In this regard, the at least one layer including the organic material can be exposed to the harmful species, e.g., ozone or H₂, such as, for example, at a side of the at least one layer that is not covered by the neighboring components or layers. The harmful species can thereby cause damage to the organic materials of the at least one layer at the portion of the electrostatic chuck between the neighboring components, which can lead to premature wear, degradation, and failure of the electrostatic chuck.

The electrostatic chuck includes the encapsulation coating, which is formed by vapor deposition. The encapsulation coating is employed to protect surfaces of the at least one layer of the electrostatic chuck including or formed of organic materials from potential degradation or damage resulting from, among other things, exposure to harmful materials, such as, for example and without imitation, ozone, H₂ plasma, etc. The encapsulation coating, when applied to one or more portions of the electrostatic chuck, forms a highly conformal coating or coating portions to seal or encapsulate organic materials or other materials similarly susceptible to degradation, thereby extending the durability and/or lifetime of the electrostatic chuck. The encapsulation coating is provided so as to cover at least a portion of the at least one component of the electrostatic chuck including the organic material. Once the vapor deposition layer is formed on a surface of the electrostatic chuck or one or more portions thereof using the encapsulation coating, it encapsulates at least the portion of the at least one layer that forms a surface of the electrostatic chuck and protects from exposure to harmful species in the harmful environment. That is, the encapsulation coating forms a vapor deposition layer covering at least the portion, or portions, of the surface of the electrostatic chuck including the at least one component that includes the organic material, and that is not covered by another component or layer of the electrostatic chuck.

In some embodiments, at least one of the layers of the electrostatic chuck can include the organic material, and the encapsulation coating can be applied to the electrostatic chuck so as to form a vapor deposition layer covering at least one portion of the electrostatic chuck. In some embodiments, the vapor deposition layer encapsulates at least the portion of the surface of the electrostatic chuck including the at least one layer including the organic material that would have been exposed to the external environment. In other embodiments, two or more layers of the electrostatic chuck can include an organic material, and the vapor deposition layer can be applied as one or more portions onto the electrostatic chuck so as to cover the portions of the two or more layers forming a surface of the electrostatic chuck, the vapor deposition layer encapsulating at least the portions of the surface of the electrostatic chuck that is formed by the respective layers including the organic material that would have been exposed to the external environment. In yet other embodiments, the encapsulating coating can be applied onto the electrostatic chuck so as to form a vapor deposition layer that substantially cover an outer surface of the electrostatic chuck, thereby encapsulating the surface of the electrostatic chuck including, but not limited to, at least one of the layers including the organic material, the other layers, components extending from the surface of one of the layers, or any combination thereof, thereby protecting the electrostatic chuck, or one or more portions thereof, from harmful materials in the harmful environments that the electrostatic chuck would have been exposed to in the external environment.

In some embodiments, the encapsulation coating covers a surface of the electrostatic chuck, or at least one portion thereof, including an organic material. In some embodiments, the encapsulation coating can cover a high aspect ratio structure having a surface including an organic material. Non-limiting examples of high-aspect ratio structures include, for example and without limitation, at least one of structure defining a plenum, a structure defining a trench, a structure defining a well, a structure defining a pore, a structure defining a hole, a structure defining an opening, a structure defining a channel, a structure defining a cavity (e.g., a partially enclosed region defining a cavity), a planar surface, a non-planar surface, or any combination thereof. As used herein, the term “high aspect ratio” refers to a structure having a ratio of two dimensions, where a width across the structure is much greater than a height of the structure. Thus, an electrostatic chuck has a high aspect ratio when a width across a respective layer of the electrostatic chuck is much greater than the height defined by the plurality of layers. Non-limiting examples of dimensions include, for example and without limitation, at least one of a length, a width, a height, a depth, a diameter, a circumference, or any combination thereof.

In some embodiments, the surface including the organic material is located in a structure having an aspect ratio of 2:1 to 1000:1, or any range or subrange therebetween. For example, the surface including the organic material is located in a structure having an aspect ratio of at least 2:1, at least 3:1, at least 4:1, at least 5:1, at least 6:1, at least 7:1, at least 8:1, at least 9:1, at least 10:1, at least 15:1, at least 20:1, at least 25:1, at least 30:1, at least 35:1, at least 40:1, at least 45:1, at least 50:1, at least 55:1, at least 60:1, at least 65:1, at least 70:1, at least 75:1, at least 80:1, at least 85:1, at least 90:1, at least 95:1, at least 100:1, at least 200:1, at least 300:1, at least 400:1, at least 500:1, at least 600:1, at least 700:1, at least 800:1, at least 900:1, to 1000:1, and/or any range or subrange therebetween.

The encapsulation coating forming the vapor deposition layer can be formed on the electrostatic chuck using a vapor deposition process so as to form a highly conformal coating or coating portions at the electrostatic chuck that seals or encapsulates the organic materials in the at least one layer or other materials similarly susceptible to degradation, thereby extending the durability and/or lifetime of the electrostatic chuck. The encapsulation coating can be a dense layer encapsulating one or more portions of the surface of the electrostatic chuck, and which is configured to be virtually free from defects as a function of the deposition process. The encapsulation coating can form a coating on the unprotected surfaces of the electrostatic chuck that conforms to the underlying component surface. The encapsulation coating can have a substantially uniform thickness of the coated portions of the electrostatic chuck. In some embodiments, the encapsulation coating can have a substantially equal thickness across the coated portions as a function of the deposition process. It is to be appreciated that the encapsulation coating is not intended to be limited to being formed on planar surfaces and can be formed on surfaces having any of a plurality of different geometries including being capable of coating complex geometries having high aspect ratios. For example, the vapor deposition layer can be suitable for coating geometries having high aspect ratios including, but not limited to, small diameter holes, deep pockets, spaces, gaps, and other geometries that may form the surface of the component including the organic material or may be between components.

The encapsulation coating may cover all, or at least a portion, of a surface including an organic material that may be exposed to the external environment of the electrostatic chuck. In some embodiments, the electrostatic chuck includes a first layer, a second layer, a third layer, and an encapsulation coating, the second layer located between the first layer and the third layer and including the organic material, and the encapsulation coating forming a vapor deposition layer that covers at least a portion of the electrostatic chuck so that the encapsulation coating covers the second layer that is not covered by the first layer and the third layer in its entirety. In some embodiments, the encapsulation coating forming the vapor deposition layer covers an outer surface of an electrostatic chuck in its entirety. For example, in some embodiments, the encapsulation coating forming the vapor deposition layer covers at least one of a top surface of the electrostatic chuck, a bottom surface of the electrostatic chuck, a side surface of the electrostatic chuck, one or more portions thereof, or any combination thereof. In some embodiments, the vapor deposition layer covers 1% to 99% of an outer surface of the electrostatic chuck, or any range or subrange between 1% and 99%. In some embodiments, the vapor deposition layer covers 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99%. In some embodiments, the encapsulation coating forming the vapor deposition layer directly contacts the surface including the organic material.

The encapsulation coating forming the vapor deposition layer can have a thickness of 10 nm to 300 nm, or any range or subrange therebetween. In some embodiments, the vapor deposition layer can have a thickness of 10 nm to 300 nm, 20 nm to 300 nm, 30 nm to 300 nm, 40 nm to 300 nm, 50 nm to 300 nm, 75 nm to 300 nm, 100 nm to 300 nm, 150 nm to 300 nm, 200 nm to 300 nm, 250 nm to 300 nm, 10 nm to 250 nm, 20 nm to 250 nm, 30 nm to 250 nm, 40 nm to 250 nm, 50 nm to 250 nm, 75 nm to 250 nm, 100 nm to 250 nm, 150 nm to 250 nm, 200 nm to 250 nm, 10 nm to 200 nm, 20 nm to 200 nm, 30 nm to 200 nm, 40 nm to 200 nm, 50 nm to 200 nm, 75 nm to 200 nm, 100 nm to 200 nm, 150 nm to 200 nm, 10 nm to 150 nm, 20 nm to 150 nm, 30 nm to 150 nm, 40 nm to 150 nm, 50 nm to 150 nm, 75 nm to 150 nm, 100 nm to 150 nm, 10 nm to 100 nm, 20 nm to 100 nm, 30 nm to 100 nm, 40 nm to 100 nm, 50 nm to 100 nm, 75 nm to 100 nm, 10 nm to 75 nm, 20 nm to 75 nm, 30 nm to 75 nm, 40 nm to 75 nm, 50 nm to 75 nm, 10 nm to 50 nm, 20 nm to 50 nm, 30 nm to 50 nm, or 40 nm to 50 nm. In some embodiments, the vapor deposition layer has a thickness of 10 nm to 300 nm. In some embodiments, the vapor deposition layer has a thickness of 10 nm to 200 nm. In some embodiments, the vapor deposition layer has a thickness of 10 nm to 250 nm. In some embodiments, the vapor deposition layer has a thickness of 30 nm to 100 nm.

In some embodiments, the encapsulation coating forming the vapor deposition layer is capable of withstanding a change in thickness in response to the electrostatic chuck being exposed to materials harmful to the organic materials or the other materials of the electrostatic chuck. In some embodiments, the encapsulation coating, when exposed to a harmful material including, for example, at least one of an ozone, a plasma, or any combination thereof, at a temperature of 10° C. to 130° C. and for a duration of 6 hours to 24 hours, a change in a thickness of the electrostatic chuck, before and after being exposed, is 10% or less, 9% or less, 8% or less, 7% or less, 6% or less, 5% or less, 4% or less, 3% or less, 2% or less, or 1% or less. In some embodiments, when the electrostatic chuck is exposed to at least one of an ozone, a plasma, or any combination thereof, at a temperature of 10° C. to 130° C. and for a duration of 6 hours to 24 hours, a change in a thickness of the electrostatic chuck, before and after being exposed, is 0.01% to 10%, 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.1% to 10%, 1% to 10%, 2% to 10%, 3% to 10%, 4% to 10%, 5% to 10%, 6% to 10%, 7% to 10%, 8% to 10%, or 9% to 10%. For example, when the electrostatic chuck is exposed to at least one of ozone atmosphere, plasma, or other harmful material that can damage the organic material, at a temperature of 100° C. and for a duration of 6 hours to 20 hours, the change in thickness of the encapsulation coating is 1% or less.

In some embodiments, when the electrostatic chuck is exposed to at least one of an ozone, a plasma, or any combination thereof, at a temperature of 10° C. to 130° C. and for a duration of 6 hours to 24 hours, a change in a metal composition of the encapsulation coating, before and after being exposed, is 10% or less, 9% or less, 8% or less, 7% or less, 6% or less, 5% or less, 4% or less, 3% or less, 2% or less, or 1% or less, as measured according to Energy-dispersive X-ray spectroscopy. In some embodiments, when the electrostatic chuck is exposed to at least one of an ozone, a plasma, or any combination thereof, at a temperature of 10° C. to 130° C. and for a duration of 6 hours to 24 hours, a change in a metal composition of the vapor deposition layer, before and after being exposed, is 0.01% to 10%, 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.1% to 10%, 1% to 10%, 2% to 10%, 3% to 10%, 4% to 10%, 5% to 10%, 6% to 10%, 7% to 10%, 8% to 10%, or 9% to 10%, as measured according to Energy-dispersive X-ray spectroscopy. For example, when the electrostatic chuck is exposed to at least one of ozone atmosphere, plasma, or other harmful material that can damage the organic material, at a temperature of 100° C. and for a duration of 6 hours to 20 hours, the change in metal composition of the encapsulation coating is less the 5%.

It is to be appreciated that the number of layers forming the electrostatic chuck is not intended to be limiting and may include one layer, two layers, three layers, four layers, five layers, six layers, or more than six layers, and with at least one of the layers including one or more components therein in accordance with the present disclosure. It is also to be appreciated that although the electrostatic chuck is described in the present disclosure as including one or more layers and one or more components, this is not intended to be limiting. In some embodiments, the encapsulating coating can be applied to the electrostatic chuck as a vapor deposition layer after the body of the electrostatic chuck is formed.

Some embodiments relate to a device. The device includes an electrostatic chuck. In some embodiments, the electrostatic chuck includes at least one of a first layer, a second layer, a third layer, a fourth layer, or any combination thereof. In some embodiments, the second layer is located between the first layer and the third layer. In some embodiments, the third layer is located between the second layer and the fourth layer. In some embodiments, each of the layers has a top surface, a bottom surface opposite the top surface, and a side surface extending between the top surface and the bottom surface. In some embodiments, at least a portion of the bottom surface of the first layer contacts at least a portion of the top surface of the second layer. In some embodiments, at least a portion of the bottom surface of the second layer contacts at least a portion of the top surface of the third layer. In some embodiments, at least a portion of the bottom surface of the third layer contacts at least a portion of the top surface of the fourth layer.

The layers of the electrostatic chuck may include at least one of a dielectric layer, an adhesive layer, a bonding layer, an insulator layer, an electrical isolation layer, or any combination thereof, among other layers. In some embodiments, the first layer is a dielectric layer. In some embodiments, the second layer is at least one of a bonding layer, an adhesive layer, an electrical isolation layer, or any combination thereof. In some embodiments, the second layer includes an organic material. In some embodiments, the third layer is an insulator layer (e.g., a supporting ceramic insulator layer). In some embodiments, the fourth layer is an electrical isolation layer (e.g., an encapsulating electrical isolation layer). In some embodiments, the fourth layer includes an organic material.

The electrostatic chuck can include at least other layer. The at least one other layer can include at least one of an electrode layer, a heater circuit layer, or any combination thereof, among other layers. In some embodiments, the at least one other layer can be located adjacent at least one layer of the electrostatic chuck. In other embodiments, the at least one other layer can be located between two layers of the electrostatic chuck. In yet other embodiments, the at least one other layer can be embedded in at least one layer of the electrostatic chuck. In some embodiments, the at least one other layer can be embedded in the at least one layer of the electrostatic chuck including the organic material. For example, in some embodiments, the at least one other layer can be an electrode layer located between the first layer and the second layer. In other embodiments, the at least one other layer can be an electrode layer embedded in the second layer between the first layer and the third layer. In another example, in some embodiments, the at least one other layer can be a heater circuit layer located between the third layer and the fourth layer. In other embodiments, the at least one other layer can be a heater circuit layer embedded in the fourth layer.

The electrostatic chuck can include at least one component. In some embodiments, the at least one component can include, but is not limited to, electrode contact pins, heater contact pins, other components, or any combination thereof, among other components. In some embodiments, the electrostatic chuck can include at least one electrode contact pin contacting the electrode layer and extending through at least one of the second layer, the third layer, the fourth layer, or any combination thereof. In some embodiments, the electrostatic chuck can include at least one heat contact pin contacting a heater circuit layer located between the third layer and the fourth layer and extending through the third layer, the fourth layer, or any combination thereof. In some embodiments, heater contact pins contact the heater circuit layer and extend through at least the fourth layer.

The second layer may be located between the first layer and the third layer such that at least a portion of the second layer is not covered by the first layer and the third layer. In some embodiments, the encapsulating coating forming the vapor deposition layer covers at least the portion of the second layer that is not covered by the first layer and the third layer. The fourth layer may be located beneath the third layer such that at least a portion of the fourth layer is not covered by the third layer. In some embodiments, the encapsulation coating forming the vapor deposition layer can cover at least the portion of the fourth layer that is not covered by the third layer. In some embodiments, the encapsulation coating can include a first portion and a second portion formed on respective portions of the electrostatic chuck, the first portion covering at least the portion of the second layer that is not covered by the first layer and the third layer and the second portion covering at least the portion of the fourth layer that is not covered by the third layer. In other embodiments, the encapsulation coating can cover an outer surface of the electrostatic chuck formed by the one or more layers in its entirety.

The electrostatic chuck may have a top surface, a bottom surface opposite the top surface, and at least one sidewall located between the top surface and the bottom surface. In addition, each of the first layer, the second layer, the third layer, and the fourth layer may have a respective top surface, a respective bottom surface opposite the respective top surface, and a respective at least one sidewall having a surface located between the top surface and the bottom surface of the corresponding layer. The electrostatic chuck includes the encapsulation coating forming the vapor deposition layer. In some embodiments, the second layer includes the organic material, and the encapsulation coating forming the vapor deposition layer covers at least the at least one sidewall of the second layer in its entirety. In some embodiments, the fourth layer includes the organic material, and the encapsulation coating forming the vapor deposition layer covers the at least one sidewall of the fourth layer. In some embodiments, the encapsulation coating forming the vapor deposition layer also covers the bottom surface of the fourth layer. The encapsulation coating can further cover other portions of the electrostatic chuck to protect these other portions from degradation or damage due to exposure to harmful materials. In some embodiments, the encapsulation coating forming the vapor deposition layer can cover at least a portion of the at least one sidewall of the first layer, a top surface of the first layer, the at least one sidewall of the third layer, one or more portions of other layers, or any combination thereof, among other components or layers. In some embodiments, the encapsulation coating forming the vapor deposition layer covers at least a portion of the top surface of the first layer. In some embodiments, the vapor deposition layer covers at least a portion of the top of the electrostatic chuck. In some embodiments, the vapor deposition layer covers at least a portion of the side of the electrostatic chuck. In some embodiments, the vapor deposition layer covers at least a portion of the bottom of the electrostatic chuck.

In some embodiments, a device includes an electrostatic chuck, the electrostatic chuck including a first layer, a second layer including an organic material, a vapor deposition layer, and a third layer, the second layer being located between the first layer and the third layer such that at least a portion of the second layer is not covered by the first layer and the third layer, the vapor deposition layer covering at least the portion of the second layer that is not covered by the first layer and the third layer.

At least one of the layers of the electrostatic chuck can include an organic material. The organic material can include, but is not limited to, at least one of acrylate polymers, polyolefins, polyamides, polyethers, polycarbonates, polysulfones, vinyl polymers, fluoropolymers, other types of polymers, or any combination thereof. In some embodiments, the organic material can include, but is not limited to, at least one of fluorinated ethylene propylene (FEP), fluoropolymer, high-density polyethylene (HDPE), low-density polyethylene (LDPE), medium-density polyethylene (MDPE), perfluoroalkoxy alkane (PFA), polybutylene (PB), poly(butyl acrylate) (PBA), poly(ethyl acrylate) (PEA), polyacrylonitrile (PAN), polyaryletherketone (PAEK), polybutadiene, polybutylene adipate terephthalate (PBAT), polybutylene succinate (PBS), polybutylene terephthalate (PBT), polychlorotrifluoroethylene (PCTFE or PTFCE), polyetherimide, polyethylene (PE), polyether ether ketone (PEEK), polyetherketoneketone (PEKK), polyethylene naphthalate (PEN), polyethylene terephthalate (PET), polyglycolide (PGA), polyphenyl sulfone (PPSU), polymethylpentene (PMP), polypropylene (PP), nylon, polyoxetane (POX), polyoxymethylene (POM), polyphenyl ether (PPE), polypropylene glycol (PPG), polystyrene (PS), polytetrafluoroethylene (PTFE), polyvinyl chloride (PVC), polyvinyl fluoride (PVF), polyvinylcarbazole (PVK), polyvinylidene chloride (PVDC), polyvinylidene fluoride (PVDF), or any combination thereof. In some embodiments, the at least one layer can include one or more organic materials as described herein. In other embodiments, the electrostatic chuck can include a plurality of layers including one or more organic materials including a first layer including at least one organic material and a second layer including at least one organic material. In some embodiments, the organic material can be a non-electrically conductive material including at least one of a fluorinated ethylene propylene (FEP), a perfluoroalkoxy alkane (PFA), a polytetrafluoroethylene (PTFE), or any combination thereof.

The first layer of the electrostatic chuck can be a dielectric layer. In some embodiments, the first layer can include, but is not limited to, at least one of alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combination thereof. In some embodiments, the first layer is a dielectric layer including an alumina ceramic.

The third layer of the electrostatic chuck can be an insulating layer. In some embodiments, the third layer can include or can be selected from a group including a ceramic material. In some embodiments, the ceramic material can include, but is not limited to, at least one of the following: alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combination thereof. In some embodiments, the third layer is an insulator layer including alumina ceramic.

In some embodiments, the portion of the second layer, which is not covered by the first layer and the third layer, is at least one sidewall of the second layer forming a portion of the side of the electrostatic chuck, and the encapsulation coating forming the vapor deposition layer can cover at least the portion of the second layer, which is not covered by the first layer and the third layer, on the side of the electrostatic chuck. In some embodiments, the encapsulation coating can cover the at least one side of the second layer and at least a portion of the first layer, the third layer, or any combination thereof. For example, the encapsulation coating can cover the second coating, a portion of the at least one side of the first layer adjacent the second layer, and a portion of the at least one side of the third layer adjacent the second layer at the side of the electrostatic chuck.

In some embodiments, the electrostatic chuck can include, at the portion of the second layer not covered by the first layer and the third layer, at least one of a hole, a trench, a well, a gap, other geometries, or any combination thereof. In some embodiments, at the portion of the side of the electrostatic chuck where the second layer meets at least one of the first layer and the third layer, can include at least one of a hole, trench, well, gap, other geometries, or any combination thereof. The encapsulation coating can be applied onto the electrostatic chuck so as to form the vapor deposition layer, and in which the encapsulation layer covers the portion of the second layer not covered by the first layer and the third layer and also covers the at least one of a hole, trench, well, gap, other geometries, or any combinations thereof, which can be formed between the second layer and at least one of the first layer and the third layer.

The electrostatic chuck includes an encapsulation coating covering one or more portions of the electrostatic chuck which is made of organic material. In some embodiments, the encapsulation coating can be formed using atomic layer deposition (ALD). In other embodiments, the encapsulation coating can be formed using chemical vapor deposition (CVD). In some embodiments, the encapsulation coating can include at least one of alumina, yttria, or a combination of alumina and yttria. As used herein, the term “atomic layer deposition” refers to a deposition technique based on the sequential exposure of two or more precursors (or reactants) to a material that reacts with a surface of the material or a portion thereof so that a thin film (e.g., the encapsulation coating) is deposited onto the surface of the material so as to produce a layered, crystalline film of uniform thickness and density. As used herein, the term “chemical vapor deposition” refers to a deposition technique based on exposing a material to one or more precursors (or reactants) that react with a surface of the material or a portion thereof while operating in at least one of atmospheric pressure, low-pressure, ultrahigh vacuum, sub-atmospheric pressure, or any combinations thereof, so as to produce a high-quality thin film of uniform thickness and density.

In some embodiments, the encapsulation coating has a thickness of 10 nm to 300 nm. In some embodiments, the encapsulation coating has a thickness of 10 nm to 200 nm. In some embodiments, the encapsulation coating has a thickness of 30 nm to 100 nm.

In some embodiments, the second layer contacts the first layer and the third layer.

In some embodiments, the encapsulation coating forming the vapor deposition layer covers 1% to 99% of an outer surface of the electrostatic chuck.

In some embodiments, the encapsulation coating forming the vapor deposition layer encapsulates at least the portion of the second layer not covered by another layer or component of the electrostatic chuck, the encapsulation coating protecting the organic materials in the second layer from a harmful material including at least one of an ozone, a plasma, or any combination thereof, the material causing at least one of degradation, change in chemical composition, change in thickness, or any combination thereof, to the organic material.

In some embodiments, in response to the electrostatic chuck being exposed to the harmful material having a first temperature for a first time period, a thickness of the encapsulation coating from the exposure is configured to change by 10% or less. In some embodiments, in response to the electrostatic chuck being exposed to the harmful material at a first temperature for a first time period, a thickness of the encapsulation coating from the exposure is configured to change by 10% or less.

In some embodiments, the electrostatic chuck further includes an electrode layer. In some embodiments, the electrode layer is disposed between the first layer and the second layer. In other embodiments, at least a portion of the electrode layer is embedded in the second layer. In some embodiments, the electrode layer includes at least one electrode pin. In some embodiments, the at least one electrode pin extends from the electrode layer to a bottom of the electrostatic chuck through at least one of the second layer, the third layer, the encapsulation coating forming the vapor deposition layer, or any combination thereof, among other layers.

In some embodiments, the electrostatic chuck further includes a fourth layer. In some embodiments, the third layer is disposed between the fourth layer and the second layer. In some embodiments, the electrostatic chuck further includes at least one heating element. In some embodiments, the at least one heating element is disposed between the third layer and the fourth layer. In other embodiments, at least a portion of the at least one heating element is embedded in the fourth layer. In some embodiments, the at least one heating element includes at least one heating element pin. In some embodiments, the at least one heating element pin extends from the at least one heating element to a bottom of the electrostatic chuck through at least the fourth layer.

In some embodiments, the fourth layer is an isolator layer.

In some embodiments, the fourth layer can include an organic material. The organic material of the fourth layer can include, but is not limited to, at least one of acrylate polymers, polyolefins, polyamides, polyethers, polycarbonates, polysulfones, vinyl polymers, fluoropolymers, other types of polymers, or any combination thereof. In some embodiments, the organic material of the fourth layer can include, but is not limited to, at least one of fluorinated ethylene propylene (FEP), fluoropolymer, high-density polyethylene (HDPE), low-density polyethylene (LDPE), medium-density polyethylene (MDPE), perfluoroalkoxy alkane (PFA), polybutylene (PB), poly(butyl acrylate) (PBA), poly(ethyl acrylate) (PEA), polyacrylonitrile (PAN), polyaryletherketone (PAEK), polybutadiene, polybutylene adipate terephthalate (PBAT), polybutylene succinate (PBS), polybutylene terephthalate (PBT), polychlorotrifluoroethylene (PCTFE or PTFCE), polyetherimide, polyethylene (PE), polyether ether ketone (PEEK), polyetherketoneketone (PEKK), polyethylene naphthalate (PEN), polyethylene terephthalate (PET), polyglycolide (PGA), polyphenyl sulfone (PPSU), polymethylpentene (PMP), polypropylene (PP), nylon, polyoxetane (POX), polyoxymethylene (POM), polyphenyl ether (PPE), polypropylene glycol (PPG), polystyrene (PS), polytetrafluoroethylene (PTFE), polyvinyl chloride (PVC), polyvinyl fluoride (PVF), polyvinylcarbazole (PVK), polyvinylidene chloride (PVDC), polyvinylidene fluoride (PVDF), or any combination thereof.

In some embodiments, the fourth layer includes at least one of fluorinated ethylene propylene (FEP), a perfluoroalkoxy alkane (PFA), a polytetrafluoroethylene (PTFE), polyethylene terephthalate (PET), or any combination thereof.

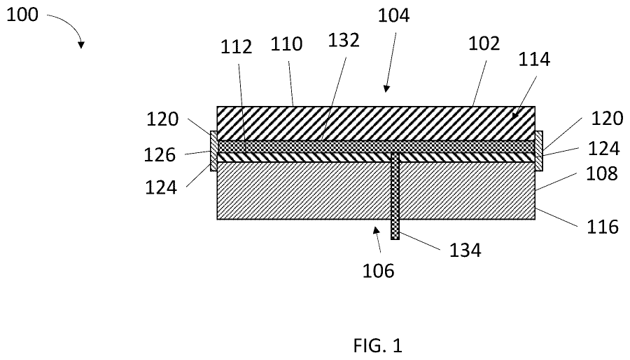

FIG. 1 is a sectional side view of a device 100, according to some embodiments.

The device 100 includes an electrostatic chuck 102 having a top 104, a bottom 106 opposite the top 104, and at least one side 108 located between the top 104 and the bottom 106. The electrostatic chuck 102 includes one or more layers. In some embodiments, the electrostatic chuck 102 has a cylindrical shape or a disk shape. Each of the layers of the electrostatic chuck includes a top surface, a bottom surface opposite the top surface, and at least one sidewall extending between the top surface and the bottom surface. In some embodiments, at least one of the layers of the electrostatic chuck 102 has a cylindrical shape or a disk shape.

According to some embodiments, the electrostatic chuck 102 includes a first layer 110, a second layer 112 including an organic material 114, a third layer 116, and an encapsulation coating 120. The second layer 112 is located between the first layer 110 and the third layer 116 such that at least a portion of the second layer 112 is not covered by the first layer 110 and the third layer 116. In addition, the encapsulation coating 120 covers at least the portion of the second layer 112 that is not covered by the first layer 110 and the third layer 116.

The first layer 110 is located adjacent the top 104 of the electrostatic chuck 102. The first layer 110 can be a dielectric layer. In some embodiments, the first layer 110 can define the top 104 of the electrostatic chuck 102. The first layer 110 can comprise, consist of, or consist essentially of materials including, but not limited to, alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combination thereof. In some embodiments, the first (dielectric) layer 110 can include ceramic alumina. In other embodiments, the first (dielectric) layer 110 can comprise, consist of, or consist essentially of alumina ceramic.

The second layer 112 contacts the first layer 110 and the third layer 116. That is, the second layer 112 can be sandwiched between the first layer 110 and the third layer 116 such that a top surface of the second layer 112 contacts a bottom surface of the first layer 110 and a bottom surface of the second layer 112 contacts top surface of the third layer 116. The second layer 112 can be at least one of an adhesive layer, a bonding layer, an electrode isolation layer, or any combination thereof.

The second layer 112 can include at least one organic material 114. The organic material can include, but is not limited to, at least one of acrylate polymers, polyolefins, polyamides, polyethers, polycarbonates, polysulfones, vinyl polymers, fluoropolymers, other types of polymers, or any combination thereof. In some embodiments, the organic material can include, but is not limited to, at least one of fluorinated ethylene propylene (FEP), fluoropolymer, high-density polyethylene (HDPE), low-density polyethylene (LDPE), medium-density polyethylene (MDPE), perfluoroalkoxy alkane (PFA), polybutylene (PB), poly(butyl acrylate) (PBA), poly(ethyl acrylate) (PEA), polyacrylonitrile (PAN), polyaryletherketone (PAEK), polybutadiene, polybutylene adipate terephthalate (PBAT), polybutylene succinate (PBS), polybutylene terephthalate (PBT), polychlorotrifluoroethylene (PCTFE or PTFCE), polyetherimide, polyethylene (PE), polyether ether ketone (PEEK), polyetherketoneketone (PEKK), polyethylene naphthalate (PEN), polyethylene terephthalate (PET), polyglycolide (PGA), polyphenyl sulfone (PPSU), polymethylpentene (PMP), polypropylene (PP), nylon, polyoxetane (POX), polyoxymethylene (POM), polyphenyl ether (PPE), polypropylene glycol (PPG), polystyrene (PS), polytetrafluoroethylene (PTFE), polyvinyl chloride (PVC), polyvinyl fluoride (PVF), polyvinylcarbazole (PVK), polyvinylidene chloride (PVDC), polyvinylidene fluoride (PVDF), or any combination thereof. The organic material 114 can include, but is not limited to, an acrylate, polyolefin, urethanes, epoxy, styrene, polysulfone, thiol, polycarbonate (PC), polyether sulfone (PES), polyether ether ketone (PEEK), polyethylene (PE), polypropylene (PP), poly vinyl chloride (PVC), polytetrafluoroethylene (PTFE), polyimide (PI), polyphenylsulfone (PPSU), polychlorotrifluoroethylene (PCTFE or PTFCE), fluorinated ethylene propylene (FEP), perfluoroalkoxy alkane (PFA), or any combination thereof. For example, the second layer 112 can be a bonding layer including FEP configured to bond the first layer 110 and the third layer 116 together. In another example, the second layer 112 can be an electrode isolation layer including PFA configured to bond the first layer 110 and the third layer 116 together. In some embodiments, the electrostatic chuck 102 can include an electrode layer 132 located between the first layer 110 and the second layer 112. In other embodiments, the second layer 112 can include at least one electrode embedded in the second layer 112, as will be further described herein. In some embodiments, the organic material is a non-electrically conductive material including at least one of a FEP, PFA, PTFE, other like organic polymeric materials, or any combination thereof.

The third layer 116 is located opposite the second layer 112 from the first layer 110. In some embodiments, the third layer 116 can be adjacent the bottom 106 of the electrostatic chuck 102. In other embodiments, the third layer 116 can define the bottom 106 surface of the electrostatic chuck 102. The third layer 116 can be formed from a ceramic material making the third layer 116 an insulator layer. The third layer 116 can include a material that has a lower dielectric resistivity compared to a dielectric resistivity of the dielectric layer. In some embodiments, the third layer 116 can include f a ceramic material. In some embodiments, the ceramic material can include, but is not limited to, at least one of the following ceramic materials: alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combination thereof. In one exemplary embodiment, the third layer 116 can be a ceramic insulator layer including alumina.

In some embodiments, as depicted in FIG. 1, the electrostatic chuck 102 includes an encapsulation coating 120. The encapsulation coating 120 encapsulates at least a portion of the electrostatic chuck 102. In some embodiments, the encapsulation coating 120 encapsulates at least a portion of the layers including organic material 114 in the electrostatic chuck 102. The encapsulation coating 120 can be formed by vapor deposition so as to form a layer on a surface of the electrostatic chuck 102. In some embodiments, the encapsulation coating 120 can be a vapor deposition layer formed using an atomic layer deposition (ALD) process forming a coating on at least the portion of the second layer 112 that is not covered by another layer of the electrostatic chuck 102, thereby encapsulating the portion of the second layer 112 that is exposed to an external environment surrounding the electrostatic chuck 102, and which may be exposed to harmful materials in a harmful environment. In other embodiments, the encapsulation coating 120 can be a vapor deposition layer formed using a chemical vapor deposition (CVD) process forming a coating on at least the portion of the second layer 112 that is not covered by another layer of the electrostatic chuck 102, thereby encapsulating the portion of the second layer 112 that is exposed to an external environment surrounding the electrostatic chuck 102, and which may be exposed to harmful materials in a harmful environment.

The encapsulation coating 120 can include alumina, yttria, or any combination thereof. In some embodiments, the encapsulating coating 120 can comprise, consist of, or consist essentially of alumina, yttria, or any combinations thereof. In some embodiments, the encapsulation coating 120 can include alumina. In other embodiments, the encapsulation coating 120 can include yttria. In yet other embodiments, the encapsulation coating 120 can include both alumina and yttria. In some embodiments, the encapsulation coating 120 includes a metal oxide.

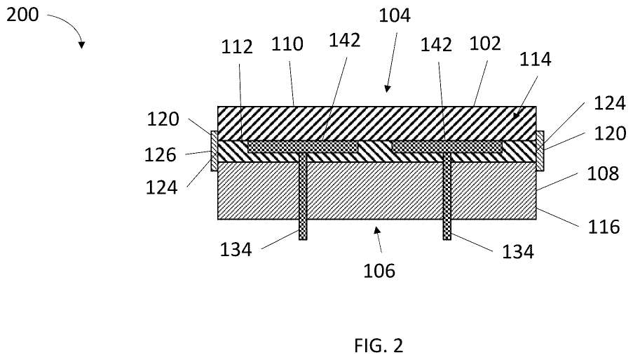

The encapsulation coating 120 can be formed using one or more methods. In some embodiments, the encapsulation coating 120 can be formed using atomic layer deposition (ALD). ALD is a technique that sequentially utilizes a gas-phase chemical process. ALD can use at least one material as a precursor (e.g., reactant). The at least one precursor is exposed to a material and reacts with a surface of the material. In some embodiments, the at least one precursor can react with at least a portion of a surface of the material including the organic material 114 so that a thin film such as, for example, film 126 shown in FIG. 2, is sequentially deposited onto the substrate of the material through sequential exposure to the at least one precursor. In some embodiments, the at least one precursor can include a first and second precursor. The film is sequentially deposited onto the substrate using the ALD process until the encapsulation coating 120 is formed as a film that encapsulates at least the portion 124 of the second layer 112 between the first layer 110 and the third layer 116. In some embodiments, the film of the encapsulation coating 120 can encapsulate one or more layers of the electrostatic chuck such as, for example, the first layer 110, second layer 112, third layer 116, one or more portions thereof, or any combination thereof.

The encapsulation coating 120 encapsulates at least the portion 124 of the second layer 112 to protect the second layer 112 (or a portion thereof) from potentially harmful material including at least one of an ozone, a plasma, other harmful materials, or any combination thereof. In some embodiments, the harmful material, if exposed to the organic materials such as, for example, in second layer 112, can cause at least one of degradation, change in chemical composition, change in thickness, or any combination thereof, to the second layer 112 and/or the electrostatic chuck 102. More particularly, the material can be harmful to the organic material 114 of the second layer 112.

In some embodiments, the portion 124 of the second layer 112, which is not covered by the first layer 110 and the third layer 116, is the at least one sidewall of the second layer 112. In addition, the encapsulation coating 120 covering at least the portion 124 of the second layer 112, which is not covered by the first layer 110 and the third layer 116, is disposed on a surface of the second layer 112 at the side, and which forms at least part of the at least one side 108 of the electrostatic chuck 102.

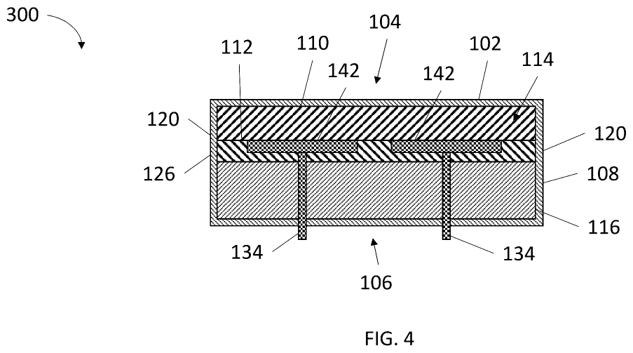

The encapsulation coating 120 can encapsulate a portion of an outer surface of the electrostatic chuck 102 corresponding to at least one layer including the organic material 114 that forms a portion of the outer surface of the electrostatic chuck 102. The encapsulation coating 120 can also encapsulate other portions of an outer surface of the electrostatic chuck 102 corresponding to other layers or components of the electrostatic chuck 102 that may or may not include organic materials, which forms a surface of the electrostatic chuck 102 along with the at least one layer including the organic material 114. In some embodiments, the encapsulation coating 120 covers 1% to 99% of an outer surface of the electrostatic chuck 102. In other embodiments, the encapsulation coating 120 can cover an entire outer surface of the electrostatic chuck 102 other than electrodes extending from the bottom 106 surface of the electrostatic chuck 102. That is, the encapsulation coating 120 can cover nearly an entire outer surface of the electrostatic chuck 102, the electrostatic chuck 102 including pins such as, for example, at least one electrode pin 134 (see FIG. 2) or at least one heating element pin 152 (see FIG. 4) extending through one or more of the layers and the encapsulation coating 120 and out the bottom 106 of the electrostatic chuck 102.

The electrostatic chuck 102 can further include an electrode layer 132 including at least one electrode located between the first layer 110 and the second layer 112. The electrode layer 132 includes a patterned metal coating formed by the at least one electrode. The electrode layer 132 includes at least one electrode pin 134 in electrical connection with the at least one electrode. The at least one electrode pin 134 can also comprise the patterned metal coating. The electrode layer 132 is configured to generate a clamping force in response to an electric current being directed through the at least one electrode pin 134 and through the at least one electrode of the electrode layer 132 so as to clamp a semiconductor wafer to the electrostatic chuck 102. The electrode layer 132 can be disposed between the first layer 110 and the second layer 112.

FIG. 2 is a side view of a device 200, according to some embodiments.

Device 200 includes electrostatic chuck 102. Electrostatic chuck 102 can include at least one electrode 142. In some embodiments, the at least one electrode 142 can be a patterned metal coating. In some embodiments, the at least one electrode 142 can be embedded in the second layer 112, the second layer 112 being located between the first layer 110 and the third layer 116 and serving as an electrode circuit layer, among other things. In some embodiments, the at least one electrode 142 can be in contact with the first layer 110. In some embodiments, at least a portion of the at least one electrode 142 can be embedded in the second layer 112. In other embodiments, the at least one electrode 142 can be embedded in the second layer 112 adjacent the first layer 110 so that a side of the at least one electrode 142 not embedded in the second layer 112 contacts a bottom of the first layer 110.

The electrostatic chuck 102 can include at least one electrode pin 134 in electrical connection with the at least one electrode 142. The at least one electrode pin 134 can extend from the at least one electrode 142 to a bottom 106 of the electrostatic chuck 102 through the one or more layers of the electrostatic chuck 102. In some embodiments, the at least one electrode pin 134 of the electrode layer 132 can extend through at least one of the second layer 112, the third layer 116, the encapsulation coating 120, or any combination thereof.

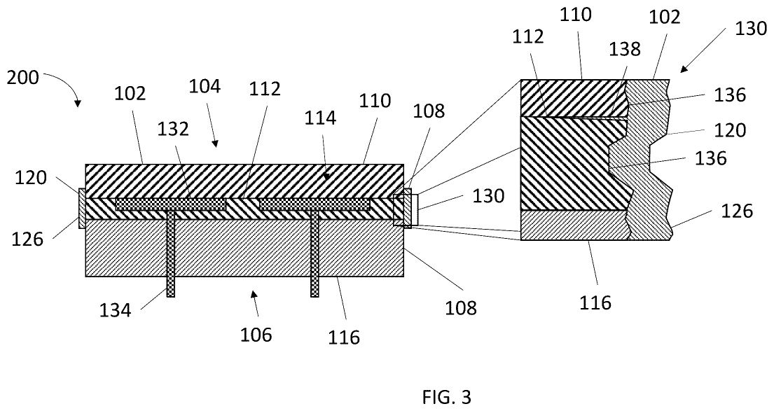

FIG. 3 is a side sectional view of a portion of the device 200 in FIG. 2, according to some embodiments.

The electrostatic chuck 102 includes first layer 110, second layer 112, third layer 116, and the encapsulation coating 120. The second layer 112 includes the organic material 114 and is sandwiched between the first layer 110 and the third layer 116, which do not comprise the organic material 114.

The encapsulation coating 120 includes a film 126 formed on at least the portion of the second layer 112 that is not covered by the first layer 110 and the third layer 116. The encapsulation coating 120 is also formed on a portion of the first layer 110 and a portion of the third layer 116 so as to encapsulate the second layer 112 from the external environment. In this regard, the encapsulation coating 120 protects the electrostatic chuck 102 in applications where the second layer 112 can be exposed to harmful species such as, for example, ozone or H₂, which can cause damage to the electrostatic chuck 102 by causing damage to the organic material 114 of the second layer 112.

The encapsulation coating 120 can have a thickness of 10 nm to 300 nm, or any range or subrange therebetween. In some embodiments, the encapsulation coating 120 can have a thickness of 10 nm to 300 nm, 20 nm to 300 nm, 30 nm to 300 nm, 40 nm to 300 nm, 50 nm to 300 nm, 75 nm to 300 nm, 100 nm to 300 nm, 150 nm to 300 nm, 200 nm to 300 nm, 250 nm to 300 nm, 10 nm to 250 nm, 20 nm to 250 nm, 30 nm to 250 nm, 40 nm to 250 nm, 50 nm to 250 nm, 75 nm to 250 nm, 100 nm to 250 nm, 150 nm to 250 nm, 200 nm to 250 nm, 10 nm to 200 nm, 20 nm to 200 nm, 30 nm to 200 nm, 40 nm to 200 nm, 50 nm to 200 nm, 75 nm to 200 nm, 100 nm to 200 nm, 150 nm to 200 nm, 10 nm to 150 nm, 20 nm to 150 nm, 30 nm to 150 nm, 40 nm to 150 nm, 50 nm to 150 nm, 75 nm to 150 nm, 100 nm to 150 nm, 10 nm to 100 nm, 20 nm to 100 nm, 30 nm to 100 nm, 40 nm to 100 nm, 50 nm to 100 nm, 75 nm to 100 nm, 10 nm to 75 nm, 20 nm to 75 nm, 30 nm to 75 nm, 40 nm to 75 nm, 50 nm to 75 nm, 10 nm to 50 nm, 20 nm to 50 nm, 30 nm to 50 nm, or 40 nm to 50 nm. In some embodiments, the encapsulation coating 120 has a thickness of 10 nm to 300 nm. In some embodiments, the encapsulation coating 120 has a thickness of 10 nm to 200 nm. In some embodiments, the encapsulation coating 120 has a thickness of 10 nm to 250 nm. In some embodiments, the encapsulation coating 120 has a thickness of 30 nm to 100 nm.

The encapsulation coating 120 is conformal to a geometry of a surface to which the film 126 is applied. The surface onto which the encapsulation coating 120 is formed can include the at least one layer of the electrostatic chuck 102 that is made of the organic material 114. The surface onto which the encapsulation coating 120 is formed can also include one or more other layers of the electrostatic chuck 102 that may not include the organic material 114. The encapsulation coating 120 can be conformal to a respective surface of the electrostatic chuck 102 having a complex geometry as a function of the deposition process, the complex geometry having a high aspect ratio. The complex geometry can be from the component including the organic material 114. In some embodiments, the complex geometry can be from neighboring layers of the electrostatic chuck 102 being formed with the at least one layer including the organic material 114. In some embodiments, the encapsulation coating 120 can conform to complex geometry having a high aspect ratio including, but not limited to, at least one of holes of large or small diameter, pores, channels, deep pockets, spaces, gaps, trenches, wells, other complex geometry, or any combination thereof.

The encapsulation coating 120 can include a substantially uniform thickness across the encapsulation coating 120. That is, the film 126 of the encapsulation coating 120 can have a nearly even thickness or equal thickness across the coated portion. The thickness of the encapsulation coating 120 can be a function of the deposition process.

Region 130 shows a portion of the first layer 110, second layer 112, third layer 116, and the encapsulation coating 120. The encapsulation coating 120 is located on a portion of the second layer 112 located between the first layer 110 and the third layer 116 which is not covered by the first layer 110 and the third layer 116, a portion of the first layer 110 adjacent to the second layer 112, and a portion of the third layer 116 adjacent to the second layer 112 opposite the first layer 110. The encapsulation coating 120 conforms to the geometry of portion of the surface 136 of the electrostatic chuck 102 including the first layer 110, second layer 112, and third layer 116. In addition, the encapsulation coating 120 can include a substantially uniform thickness across the film 126 covering the surface 136. That is, the portion of the surface 136 of the electrostatic chuck 102 can include a complex geometry and the film 126 of the encapsulation coating 120 can be conformal to the geometry of the portion of the surface 136. In this regard, the encapsulation coating 120 coating the portion of the surface 136 of the electrostatic chuck 102 can have a uniform thickness that is conformation to the geometry of the portion of the surface 136 at the electrostatic chuck 102.

In some embodiments, the portion of the surface 136 of the electrostatic chuck 102 can include at least one surface defect 138. In some embodiments, the portion of the second layer 112, which is not covered by the first layer 110 and the third layer 116, can further include the at least one surface defect 138. In some embodiments, the at least one surface defect 138 can be formed by at least one of the first layer 110, second layer 112, third layer 116, or any combination thereof, among other layers. In some embodiments, the at least one surface defect 138 can include, but is not limited to, at least one of a hole, a pore, a trench, a well, a gap, a channel, other defects, or any combination thereof, which is formed by at least one of the first layer, the second layer, the third layer, other layers, or any combinations thereof, and which can include a complex geometry having a high aspect ratio.

In some embodiments, in response to the electrostatic chuck 102 being exposed to the harmful material at a first temperature for a first time period, a thickness of the encapsulation coating 120 from the exposure is configured to change by 10% or less.

In some embodiments, in response to the electrostatic chuck 102 being exposed to the harmful species or material at the first temperature for the first time period, a metal composition of the encapsulation coating 120 from the exposure is configured to change by 10% or less.

FIG. 4 is a sectional side view of the device 300, according to some embodiments.

The encapsulation coating 120 can encapsulate one or more of the layers of the electrostatic chuck 102. That is, the encapsulation coating 120 can include a film 126 that covers not only the portion of the second layer 112 that is between the first layer 110 and the third layer 116 and not covered by the first layer 110 and the third layer 116, but the film 126 also covers the entire outer surface of the electrostatic chuck 102 including the first layer 110, second layer 112, and third layer 116. In some embodiments, the electrostatic chuck 102 can include the first layer 110, the second layer 112, the third layer 116, and one or more other layers, and the film 126 can cover an entirety of the electrostatic chuck 102 and the layers.

The electrostatic chuck 102 can further include the at least one electrode 142 forming a patterned metal coating and embedded in the second layer 112. In some embodiments, the at least one electrode 142 can be an electrode layer 132 arranged between the first layer 110 and the second layer 112. The at least one electrode 142 can be connected to at least one electrode pin 134. In some embodiments, the at least one electrode pin 134 can extend from the at least one electrode 142 and through one or more of the layers of the electrostatic chuck 102 and out through the bottom 106 of the electrostatic chuck 102. In some embodiments, the at least one electrode pin 134 can extend from the at least one electrode 142 and through the second layer 112, third layer 116, or both the second layer 112 and third layer 116, among other layers. Referring to FIG. 4, the at least one electrode pin 134 extends through from the respective at least one electrode 142 and through the second layer 112, third layer 116, and one or more portions of the encapsulation coating 120.

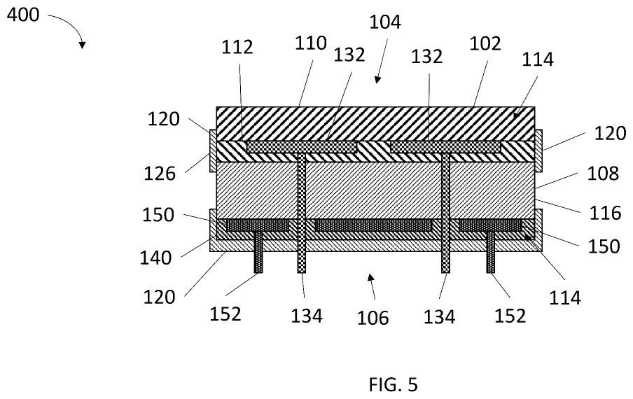

FIG. 5 is a sectional side view of a device 400, according to some embodiments.

At device 400, the electrostatic chuck 102 includes first layer 110, second layer 112, third layer 116, and fourth layer 140. The electrostatic chuck 102 includes an encapsulation coating 120. In some embodiments, the second layer 112 can be located between the first layer 110 and the third layer 116, and the encapsulation coating 120 can be formed on at least a portion of the second layer 112 that is not covered by the first layer 110 and third layer 116. In some embodiments, the fourth layer 140 can be located adjacent the third layer 116 at the bottom 106 of the electrostatic chuck 102. That is, the third layer 116 can be disposed between the fourth layer 140 and the second layer 112, and the fourth layer 140 can define the bottom layer of the electrostatic chuck 102. In some embodiments, the encapsulation coating 120 can also be formed on at least a portion of the fourth layer 140 that is not covered by the third layer 116. In this regard, in some embodiments, the encapsulation coating 120 can include respective portions covering a corresponding layer that includes the organic material 114 and is not covered by another layer of the electrostatic chuck 102.

The fourth layer 140 can be an insulator layer, according to some embodiments. In some embodiments, the fourth layer 140 can include the organic material 114. In other embodiments, the fourth layer 140 can include, consist of, or consist essentially of the organic material 114. In some embodiments, the fourth layer 140 can include organic material 114 including, but not limited to, at least one of acrylate polymers, polyolefins, polyamides, polyethers, polycarbonates, polysulfones, vinyl polymers, fluoropolymers, other types of polymers, or any combinations thereof. In some embodiments, the organic materials 114 can include, but are not limited to, at least one of fluorinated ethylene propylene (FEP), fluoropolymer, high-density polyethylene (HDPE), low-density polyethylene (LDPE), medium-density polyethylene (MDPE), perfluoroalkoxy alkane (PFA), polybutylene (PB), poly(butyl acrylate) (PBA), poly(ethyl acrylate) (PEA), polyacrylonitrile (PAN), polyaryletherketone (PAEK), polybutadiene, polybutylene adipate terephthalate (PBAT), polybutylene succinate (PBS), polybutylene terephthalate (PBT), polychlorotrifluoroethylene (PCTFE or PTFCE), polyetherimide, polyethylene (PE), polyether ether ketone (PEEK), polyetherketoneketone (PEKK), polyethylene naphthalate (PEN), polyethylene terephthalate (PET), polyglycolide (PGA), polyphenyl sulfone (PPSU), polymethylpentene (PMP), polypropylene (PP), nylon, polyoxetane (POX), polyoxymethylene (POM), polyphenyl ether (PPE), polypropylene glycol (PPG), polystyrene (PS), polytetrafluoroethylene (PTFE), polyvinyl chloride (PVC), polyvinyl fluoride (PVF), polyvinylcarbazole (PVK), polyvinylidene chloride (PVDC), polyvinylidene fluoride (PVDF), or any combinations thereof. In some embodiments, the fourth layer 140 is an isolator layer including at least one of fluorinated ethylene propylene (FEP), a perfluoroalkoxy alkane (PFA), a polytetrafluoroethylene (PTFE), polyimide (PI), polyethylene terephthalate (PET), or any combinations thereof.

Referring the FIG. 5, the electrostatic chuck 102 includes the first layer 110, second layer 112, third layer 116, the fourth layer 140, and the encapsulation coating 120. The second layer 112 and the fourth layer 140 include the organic material 114. The portion of the second layer 112, which is not covered by the first layer 110 and the third layer 116, is at least one side of the second layer 112. The encapsulation coating 120 can include a respective portion that covers the at least one side of the second layer 112, which is not covered by the first layer 110 and the third layer 116. In some embodiments, the respective portion of the encapsulation coating 120 covering the second layer 112 can also cover at least a portion of the first layer 110, the third layer 116, or both the second layer 112 and the third layer 116. The portion of the fourth layer 140, which is not covered by the third layer 116, defines the bottom 104 of the electrostatic chuck 102 and at least one side of the fourth layer 140. The encapsulation coating 120 can further include a respective portion that covers the bottom and at least one side of the fourth layer 140. In some embodiments, the respective portion of the encapsulation coating 120 covering the bottom and at least one side of the fourth layer 140 can also cover at least a portion of the third layer 116. As such, the encapsulation coating 120 can cover at least the portions of the electrostatic chuck 102 that comprise the organic material 114 including the second layer 112 and the fourth layer 140 that are not covered by the other components of the electrostatic chuck 102 to protect the layers including the organic material 114 from damage caused by exposure to harmful materials.

The electrostatic chuck 102 can further include at least one heating element 150, according to some embodiments. The at least one heating element 150 includes a patterned metal coating. The at least one heating element 150 can be disposed between the third layer 116 and the fourth layer 140. In some embodiments, the at least one heating element 150 can be embedded in the fourth layer 140. In some embodiments, at least a portion of the at least one heating element 150 can be embedded in the fourth layer 140 and contacts a bottom of the third layer 116, the fourth layer 140 serving as a heater circuit layer, among other things.

The at least one heating element 150 can include at least one heating element pin 152 in electrical connection with the at least one heating element 150. The at least one heating element pin 152 extends from the at least one heating element 150 to a bottom 106 of the electrostatic chuck 102 through at least the fourth layer 140. The at least one heating element 150 is configured to generate heat in response to an electric current being applied to the at least one heating element pin 152, thereby heating the body of the electrostatic chuck 102 and maintaining the electrostatic chuck 102 at a certain temperature or temperature range. In some embodiments, the at least one heating element pin 152 can extend through the fourth layer 140 and the portion of the encapsulation coating 120 that covers the fourth layer 140 so as to extend from the bottom 106 of the electrostatic chuck 102.

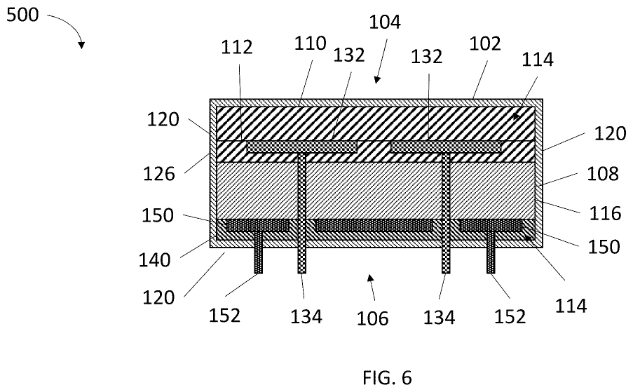

FIG. 6 is a sectional side view of the device 500, according to some embodiments.

The encapsulation coating 120 can encapsulate one or more of the layers of the electrostatic chuck 102. The encapsulation coating 120 can encapsulate those layers including the organic material 114 but can also encapsulate layers that do not include the organic material 114. That is, the encapsulation coating 120 can include a film 126 that covers not only the portion of the second layer 112 that is between the first layer 110 and the third layer 116 and the portion of the fourth layer 140 that is at the bottom of the electrostatic chuck 102, but the encapsulation coating 120 can cover the entire outer surface of the electrostatic chuck 102 including first layer 110, second layer 112, third layer 116, and fourth layer 140.

According to some embodiments, the electrostatic chuck 102 can include one or more layers, at least one of the layers including the organic material 114 therein. In some embodiments, the electrostatic chuck 102 can further include at least one electrode 142 for enabling the electrostatic chuck 102 to clamp onto a substrate and can further include the at least one heating element 150 for regulating a temperature at the electrostatic chuck 102. Theat least one electrode 142 including the at least one electrode pin 134 in electrical connection with the at least one electrode 142 and extending out the bottom 106 of the electrostatic chuck 102. The at least one heating element 150 including the at least one heating element pin 152 in electrical connection with the at least one heating element 150 and extending out the bottom 106 of the electrostatic chuck 102. Referring to FIG. 6, for example, in some embodiments, the at least one electrode pin 134 and the at least one heating element pin 152 can extend through one or more respective layers of the electrostatic chuck 102 and out through the bottom 106 of the electrostatic chuck 102. In this regard, in some embodiments, the at least one electrode pin 134 can extend through the second layer 112, third layer 116, fourth layer 140, and a respective portion of the encapsulation coating 120, and the at least one heating element pin 152 can extend through the fourth layer 140 and a respective portion of the encapsulation coating 120.

It is to be appreciated that the electrostatic chuck 102 can include one or more layers, and of the one or more layers of the electrostatic chuck 102, at least one of the layers can include the organic material 114 therein. In addition, it is to be appreciated that the arrangement of the respective layers of the electrostatic chuck 102 as shown in the figures are exemplary and not intended to be limiting. In this regard, the electrostatic chuck 102 can include one or more layers arranged in any of a plurality of configurations and in any of a plurality of different combinations thereof. It is also to be appreciated that unless specified, the shape, size, and dimensions of the respective layers and respective components in the electrostatic chuck 102, and as shown in the figures, are exemplary and not intended to be limiting. Accordingly, the electrostatic chuck 102 and the one or more components of the electrostatic chuck 102 can include any of a plurality of different shapes, sizes, and dimensions in accordance with the present disclosure.

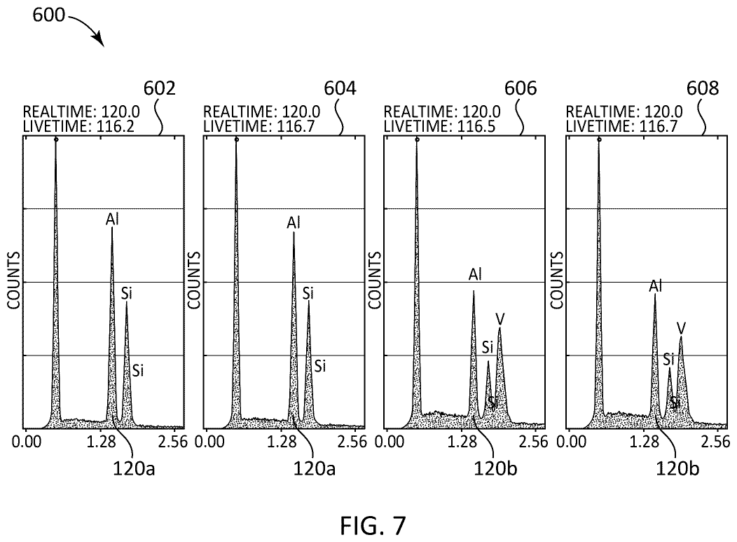

FIG. 7 is a non-limiting example of a graph 600 illustrating changes in chemical compositions, according to some embodiments.

The device 100, 200, 300, 400, 500 includes an electrostatic chuck 102 including one or more layers, at least one of the layers including the organic material 114. For example, the electrostatic chuck 102 can comprise the second layer 112, as shown in FIG. 1. In another example, the electrostatic chuck 102 can comprise the second layer 112 and the fourth layer 140 as shown in FIG. 4. The electrostatic chuck 102 further includes the encapsulation coating 120 encapsulating at least the portions of the electrostatic chuck 102 including the components made of the organic material 114, to protect these components from damage caused by exposure to the harmful materials.

Without the encapsulation coating 120 covering the at least one layer made of the organic material 114, the electrostatic chuck 102 being exposed to the harmful materials such as, for example, ozone, plasma, and other like harmful materials, can cause degradation of the at least one layer. Degradation of the at least one layer can include a change in chemical composition of the at least one layer, change in thickness of the at least one layer, or any combination thereof. In this regard, the encapsulation coating 120 encapsulates the at least one layer including the organic material 114 that is not covered by another layer or component of the electrostatic chuck 102, and resists degradation from the harmful materials that can damage the at least one layer including the organic material 114. By the encapsulation coating 120 encapsulating at least the portions of the electrostatic chuck 102 including the at least one layer made of the organic material 114, the encapsulation coating 120 protects the at least one layer made of the organic material 114 from damage.

The encapsulation coating 120 can include one or more materials including, but not limited to, alumina, yttria, metal oxides, or any combinations thereof. In some embodiments, the encapsulation coating 120 can include alumina. In some embodiments, the encapsulation coating 120a can further include one or more other materials. For example, in some embodiments, the other materials can include non-organic materials such as, for example, silicon.

At subgraph 602, a chemical composition of the encapsulation coating 120a is shown before exposure to the harmful material, the encapsulation coating 120a having a first thickness. It is to be appreciated that the thickness of the encapsulation coating 120a is exemplary and not intended to be limiting. Instead, the thickness of the encapsulation coating 120a at subgraph 202 is for enabling testing of the properties of the encapsulation coating 120a resulting from exposure to the harmful material.

At subgraph 604, the chemical composition of the encapsulation coating 120a is shown after exposure to the harmful material having a first temperature for a first period of time. In response to the electrostatic chuck 102 being exposed to the harmful material at the first temperature for the first time period, a chemical composition of the encapsulation coating 120a from the exposure changes by 10% or less. In some embodiments, in response to the electrostatic chuck 102 being exposed to the harmful material at the first temperature for the first time period, a chemical composition of the encapsulation coating 120a from the exposure changes by 5% or less. For example, the composition of alumina in the encapsulation coating 120 after exposure changes by approximately 1.53%. In other embodiments, in response to the electrostatic chuck 102 being exposed to the material at the first temperature for the first time period, a chemical composition of the encapsulation coating 120a from the exposure changes by 1% or less. For example, the composition of the encapsulation coating 120a after exposure can change by approximately 0.66%.

In response to the electrostatic chuck 102 being exposed to the material at the first temperature for the first time period, a thickness of the encapsulation coating 120a from the exposure changes by 10% or less. In some embodiments, in response to the electrostatic chuck 102 being exposed to the material at the first temperature for the first time period, the thickness of the encapsulation coating 120a from the exposure changes by 5% or less. In other embodiments, in response to the electrostatic chuck 102 being exposed to the material having the first temperature for the first time period, the thickness of the encapsulation coating 120a from the exposure changes by 2% or less. For example, the thickness of the encapsulation coating 120a after exposure can change by approximately 1.51%.

The encapsulation coating 120 can include yttria. In some embodiments, the encapsulation coating 120b can include alumina and yttria. In some embodiments, the encapsulation coating 120b can further include one or more other materials. The other materials can include non-organic materials such as, for example, silicon.

At subgraph 606, a chemical composition of the encapsulation coating 120b is shown before exposure to the harmful material, the encapsulation coating 120b having a second thickness. It is to be appreciated that the thickness of the encapsulation coating 120b is exemplary and not intended to be limiting. Instead, the thickness of the encapsulation coating 120b at subgraph 606 is for enabling testing of the properties of the encapsulation coating 120b resulting from exposure to the harmful material.

At subgraph 608, the chemical composition of the encapsulation coating 120b is shown after exposure to the harmful material at a first temperature for a first period of time. In response to the electrostatic chuck 102 being exposed to the material at the first temperature for the first time period, a chemical composition of the encapsulation coating 120b from the exposure is configured to change by 10% or less. In some embodiments, in response to the electrostatic chuck 102 being exposed to the material at the first temperature for the first time period, a chemical composition of the encapsulation coating 120b from the exposure is configured to change by 5% or less. For example, the chemical composition of the encapsulation coating 120b following exposure can change by approximately 2.14%. In other embodiments, in response to the electrostatic chuck 102 being exposed to the material at the first temperature for the first time period, a chemical composition of the encapsulation coating 120b from the exposure is configured to change by 1% or less. For example, the chemical composition of the encapsulation coating 120b following exposure can change by approximately 0.22%.

In response to the electrostatic chuck 102 being exposed to the material at the first temperature for the first time period, a thickness of the encapsulation coating 120b from the exposure is configured to change by 10% or less. In some embodiments, in response to the electrostatic chuck 102 being exposed to the material at the first temperature for the first time period, the thickness of the encapsulation coating 120b from the exposure is configured to change by 5% or less. In other embodiments, in response to the electrostatic chuck 102 being exposed to the material at the first temperature for the first time period, the thickness of the encapsulation coating 120b from the exposure is configured to change by 2% or less. For example, the thickness of the encapsulation coating 120a after exposure can change by approximately 0.39%.

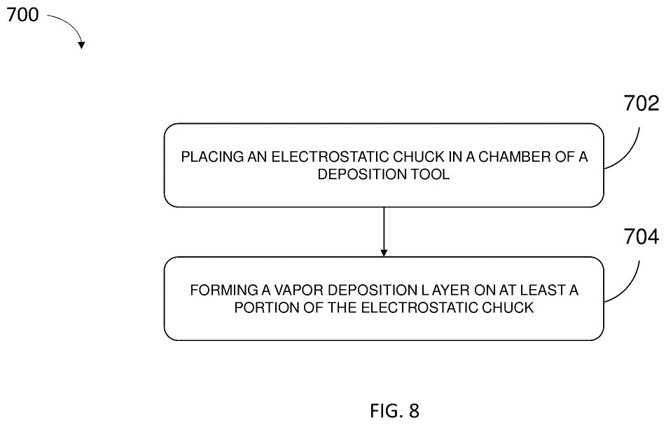

FIG. 8 is a flowchart of a method 700 of forming an encapsulation coating on an electrostatic chuck, according to some embodiments. As shown in FIG. 8, in some embodiments, the method 700 of forming the encapsulation coating on an electrostatic chuck includes one or more of the following steps: placing 702 an electrostatic chuck in a chamber of a deposition tool; and forming 704 a vapor deposition layer on at least a portion of the electrostatic chuck. In some embodiments, the method 700 can further include obtaining an electrostatic chuck prior to placing the electrostatic chuck in the deposition tool. The electrostatic chuck may include any of the one or more of the electrostatic chucks disclosed herein. In some embodiments, the forming 704 includes forming, via atomic layer deposition, a vapor deposition layer on at least a portion of the electrostatic chuck. In some embodiments, the forming 704 includes forming, via chemical vapor deposition, a vapor deposition layer on at least a portion of the electrostatic chuck. The vapor deposition layer may be formed on the electrostatic chuck at any of the locations disclosed herein.

### Aspects

Aspect 1. An electrostatic chuck comprising:
a first layer;
a second layer comprising an organic material;
a encapsulation coating; and
a third layer;
wherein the second layer is located between the first layer and the third layer such that at least a portion of the second layer is not covered by the first layer and the third layer;
wherein the encapsulation coating covers at least the portion of the second layer that is not covered by the first layer and the third layer.

Aspect 2. The electrostatic chuck according to aspect 1, wherein the encapsulation coating is a highly conformal layer.

Aspect 3. The electrostatic chuck according to any of the preceding aspects, wherein the encapsulation coating comprises at least one of yttria, alumina, or any combination thereof.

Aspect 4. The electrostatic chuck according to any of the preceding aspects, wherein the encapsulation coating further covers at least a portion of the first layer and the third layer adjacent the second layer.

Aspect 5. The electrostatic chuck according to any of the preceding aspects, wherein the vapor deposition layer has a thickness of 5 nm to 300 nm.

Aspect 6. The electrostatic chuck according to any of the preceding aspects, wherein the organic material comprises at least one of acrylate polymers, polyolefins, polyamides, polyethers, polycarbonates, polysulfones, vinyl polymers, fluoropolymers, or any combination thereof.

Aspect 7. The electrostatic chuck according to any of the preceding aspects, wherein the organic material comprises at least one of fluorinated ethylene propylene (FEP), fluoropolymer, high-density polyethylene (HDPE), low-density polyethylene (LDPE), medium-density polyethylene (MDPE), perfluoroalkoxy alkane (PFA), polybutylene (PB), poly(butyl acrylate) (PBA), poly(ethyl acrylate) (PEA), polyacrylonitrile (PAN), polyaryletherketone (PAEK), polybutadiene, polybutylene adipate terephthalate (PBAT), polybutylene succinate (PBS), polybutylene terephthalate (PBT), polychlorotrifluoroethylene (PCTFE or PTFCE), polyetherimide, polyethylene (PE), polyether ether ketone (PEEK), polyetherketoneketone (PEKK), polyethylene naphthalate (PEN), polyethylene terephthalate (PET), polyglycolide (PGA), polyphenyl sulfone (PPSU), polymethylpentene (PMP), polypropylene (PP), nylon, polyoxetane (POX), polyoxymethylene (POM), polyphenyl ether (PPE), polypropylene glycol (PPG), polystyrene (PS), polytetrafluoroethylene (PTFE), polyvinyl chloride (PVC), polyvinyl fluoride (PVF), polyvinylcarbazole (PVK), polyvinylidene chloride (PVDC), polyvinylidene fluoride (PVDF), or any combination thereof.

Aspect 8. The device according to any of the preceding aspects, wherein the encapsulation coating covers a surface of the second layer including at least one surface defect having an aspect ratio of 1:1 to 1000:1.

Aspect 9. The device according to any of the preceding aspects, the encapsulation coating covers, in its entirety, the portion of the second layer that is not covered by the first layer and the third layer.

Aspect 10. The device according to any of the preceding aspects, wherein, after the electrostatic chuck is exposed to at least one of an ozone atmosphere, a plasma, or any combination thereof, at a temperature of 10° C. to 130° C. and for a duration of 6 hours to 24 hours, a change in a thickness of the electrostatic chuck is 1% or less.

Aspect 11. The device according to any of the preceding aspects, wherein, after the electrostatic chuck is exposed to at least one of an ozone atmosphere, a plasma, or any combination thereof, at a temperature of 10° C. to 130° C. and for a duration of 6 hours to 20 hours, a change in a metal composition of the vapor deposition layer, is 10% or less as measured according to Energy-dispersive X-ray spectroscopy.

Aspect 12. A device comprising:
an electrostatic chuck,
wherein the electrostatic chuck comprises:
a first layer;
a second layer comprising an organic material;
a third layer; and
an encapsulation coating;
wherein the second layer is located between the first layer and the third layer such that at least a portion of the second layer is not covered by the first layer and the third layer;
wherein the encapsulation coating is a conformal film covering at least the portion of the second layer that is not covered by the first layer and the third layer.

Aspect 13. The device according to aspect 12, wherein at least a portion of a bottom surface of the first layer contacts at least a portion of a top surface of the second layer.

Aspect 14. The device according to aspects 12 or 13, wherein at least a portion of a bottom surface of the second layer contacts at least a portion of a top surface of the third layer.

Aspect 15. The device according to aspects 12, 13, or 14, wherein the first layer is a dielectric layer, the second layer is a bonding layer, and the third layer is an insulator layer.

Aspect 16. The device according to aspects 12, 13, 14, or 15, further comprising:
a fourth layer comprising an organic material,
wherein the third layer is located between the second layer and the fourth layer;
wherein the encapsulation coating further covers at least a portion of the fourth layer that is not covered by the third layer.

Aspect 17. The device according to aspect 16, wherein each of the first layer, the second layer, the third layer, and the fourth layer has:
a top surface,
a bottom surface opposite the top surface, and
a side surface located between the top surface and the bottom surface,
wherein the encapsulation coating covers at least one of the bottom surface of the fourth layer, the side surface of the fourth layer, or any combination thereof.

Aspect 18. The device according to aspect 17, wherein at least a portion of the bottom surface of the third layer contacts at least a portion of the top surface of the fourth layer.

Aspect 19. The device according to aspects 12, 13, 14, 15, 16, 17, or 18, wherein the first layer is a dielectric layer, the second layer is a bonding layer, the third layer is an insulator layer, and the fourth layer is a heater circuit layer.

Aspect 20. A method comprising:
placing an electrostatic chuck in a chamber of a deposition tool,
wherein the electrostatic chuck comprises:
   a first layer;
   a second layer comprising an organic material; and
   a third layer;
   wherein the second layer is located between the first layer and the third layer such that at least a portion of the second layer is not covered by the first layer and the third layer; and
forming an encapsulation coating on at least the portion of the second layer that is not covered by the first layer and the third layer.

Aspect 21. The method according to aspect 20, wherein the encapsulation coating is formed using atomic layer deposition.

Aspect 22. The method according to aspects 20 or 21, wherein the encapsulation coating is formed using chemical vapor deposition.

Aspect 23. The method according to aspects 20, 21, or 22, wherein the encapsulation coating comprises ceramic alumina.

Aspect 24. The method according to aspects 20, 21, 22, or 23, wherein the encapsulation coating comprises yttria.

What is claimed is:

1. An electrostatic chuck comprising:
a first layer;
a second layer comprising an organic material;
a third layer, wherein the second layer is located between the first layer and the third layer such that at least a portion of the second layer is not covered by the first layer and the third layer; and
an encapsulation coating, wherein the encapsulation coating covers at least the portion of the second layer that is not covered by the first layer and the third layer.

2. The electrostatic chuck of claim 1, wherein the encapsulation coating is a highly conformal layer.

3. The electrostatic chuck of claim 2, wherein the encapsulation coating comprises at least one of yttria, alumina, or any combination thereof.

4. The electrostatic chuck of claim 1, wherein the encapsulation coating further covers at least a portion of the first layer and the third layer adjacent the second layer.

5. The electrostatic chuck of claim 1, wherein the vapor deposition layer has a thickness of 5 nm to 300 nm.

6. The electrostatic chuck of claim 1, wherein the organic material comprises at least one of acrylate polymers, polyolefins, polyamides, polyethers, polycarbonates, polysulfones, vinyl polymers, fluoropolymers, or any combination thereof.

7. The electrostatic chuck of claim 6, wherein the organic material comprises at least one of fluorinated ethylene propylene (FEP), fluoropolymer, high-density polyethylene (HDPE), low-density polyethylene (LDPE), medium-density polyethylene (MDPE), perfluoroalkoxy alkane (PFA), polybutylene (PB), poly(butyl acrylate) (PBA), poly(ethyl acrylate) (PEA), polyacrylonitrile (PAN), polyaryletherketone (PAEK), polybutadiene, polybutylene adipate terephthalate (PBAT), polybutylene succinate (PBS), polybutylene terephthalate (PBT), polychlorotrifluoroethylene (PCTFE or PTFCE), polyetherimide, polyethylene (PE), polyether ether ketone (PEEK), polyetherketoneketone (PEKK), polyethylene naphthalate (PEN), polyethylene terephthalate (PET), polyglycolide (PGA), polyphenyl sulfone (PPSU), polymethylpentene (PMP), polypropylene (PP), nylon, polyoxetane (POX), polyoxymethylene (POM), polyphenyl ether (PPE), polypropylene glycol (PPG), polystyrene (PS), polytetrafluoroethylene (PTFE), polyvinyl chloride (PVC), polyvinyl fluoride (PVF), polyvinylcarbazole (PVK), polyvinylidene chloride (PVDC), polyvinylidene fluoride (PVDF), or any combination thereof.

8. The electrostatic chuck of claim 1, wherein the encapsulation coating covers a surface of the second layer including at least one surface defect having an aspect ratio of 1:1 to 1000:1.

9. The electrostatic chuck of claim 1, the encapsulation coating covers, in its entirety, the portion of the second layer that is not covered by the first layer and the third layer.

10. The electrostatic chuck of claim 1, wherein, after the electrostatic chuck is exposed to at least one of an ozone atmosphere, a plasma, or any combination thereof, at a temperature of 10° C. to 130° C. and for a duration of 6 hours to 24 hours, a change in a thickness of the electrostatic chuck is 1% or less.

11. The electrostatic chuck of claim 1, wherein, after the electrostatic chuck is exposed to at least one of an ozone atmosphere, a plasma, a chemical vapor, a reactive gas, a corrosive environment, or any combination thereof, at a temperature of 10° C. to 130° C. and for a duration of 6 hours to 20 hours, a change in a metal composition of the vapor deposition layer, is 10% or less as measured according to Energy-dispersive X-ray spectroscopy.

12. A method comprising:
placing an electrostatic chuck in a chamber of a deposition tool,
wherein the electrostatic chuck comprises:
a first layer;
a second layer comprising an organic material; and
a third layer;
wherein the second layer is located between the first layer and the third layer such that at least a portion of the second layer is not covered by the first layer and the third layer; and
forming an encapsulation coating on at least the portion of the second layer that is not covered by the first layer and the third layer.

13. The method of claim 12, wherein the encapsulation coating is formed using atomic layer deposition.

14. The method of claim 12, wherein the encapsulation coating is formed using chemical vapor deposition.

15. The method of claim 12, wherein the encapsulation coating comprises ceramic alumina.

16. The method of claim 12, wherein the encapsulation coating comprises yttria.
